(19) United States
(12) Patent Application Publication
(10) Pub. No.: US 2026/0223461 A1
(43) Pub. Date: Jul. 30, 2026

(54) SEMICONDUCTOR DEVICE AND METHOD OF MANUFACTURING SEMICONDUCTOR DEVICE

(71) Applicants: FUJI ELECTRIC CO., LTD., Kawasaki-shi (JP); DENSO CORPORATION, Kariya-city (JP)

(72) Inventors: Hiroki NAKAYA, Matsumoto-city (JP); Takaaki SUZAWA, Matsumoto-city (JP); Kota OHI, Matsumoto-city (JP); Keita HAYASHI, Kariya-city (JP)

(73) Assignees: FUJI ELECTRIC CO., LTD., Kawasaki-shi (JP); DENSO CORPORATION, Kariya-city (JP)

(21) Appl. No.: 19/437,860

(22) Filed: Dec. 31, 2025

(30) Foreign Application Priority Data
Jan. 24, 2025 (JP) 2025-011003

(51) Int. Cl. H10D 89/60; H10D 8/00

(52) U.S. Cl. CPC H10D 89/611; H10D 8/411

(57) ABSTRACT

A semiconductor device, including: an insulating film provided on a substrate; a cathode region and an anode region, with a low-concentration region therebetween, provided on the insulating film, the low-concentration region having a dopant concentration lower than that of the cathode region and that of the anode region; an interlayer insulating film covering the cathode region, the anode region, and the low-concentration region, the interlayer insulating film having a first contact hole and a second contact hole penetrating therethrough; a cathode electrode and an anode electrode provided on the interlayer insulating film, and connected to the cathode region and the anode region via the first contact hole and the second contact hole, respectively. In a top view of the semiconductor device, the cathode or anode electrode overlaps an upper portion of the low-concentration region by 4 μm or more in a direction from the cathode region to the anode region.

### CROSS REFERENCE TO RELATED APPLICATIONS

This application is based upon and claims the benefit of priority of the prior Japanese Patent Application No. 2025-011003, filed on January 24, 2025, the entire contents of which are incorporated herein by reference.

### BACKGROUND OF THE INVENTION

### 1. Field of the Invention

Embodiments of the disclosure relate to a semiconductor device and a method of manufacturing a semiconductor device.

### 2. Description of the Related Art

In insulated gate bipolar transistors (IGBTs) and metal oxide semiconductor field effect transistors (MOSFETs), an additional functional structure having a detecting element such as a temperature sensing portion that detects temperature and protects against high temperatures is provided to enhance reliability. In the additional functional structure, for example, additional functional portions such as a current sensing portion, a temperature sensing portion, and an overvoltage protecting portion are disposed.

FIG. 16 is a cross-sectional view depicting a structure of a temperature sensing diode of a conventional semiconductor device. A temperature sensing diode 152 is a diode provided in a temperature sensing portion to detect temperature. In the conventional temperature sensing diode 152, an n⁺-type cathode region 126 and a p⁺-type anode region 128 are provided on a field oxide film 132 that is on a semiconductor substrate 144 in which semiconductor device element such as an IGBT or a MOSFET is formed. Further, a p⁻-type low-concentration region 130 or an n⁻-type low-concentration region (not depicted) is provided between the n⁺-type cathode region 126 and the p⁺-type anode region 128. In a known semiconductor device, the p⁻-type low- concentration region 130 (or the n⁻-type low-concentration region) stabilizes distribution of the dopant concentration of a pn junction portion and a vicinity thereof, reduces variation of forward voltage of a diode, and increases accuracy of temperature detection (for example, refer to Japanese Laid-Open Patent Publication No. 2002-190575).

An interlayer insulating film 124 is provided on the n⁺-type cathode region 126, the p⁺-type anode region 128, and the p⁻-type low-concentration region 130; and through openings in the interlayer insulating film 124, a cathode electrode 134 is connected to the n⁺-type cathode region 126 and an anode electrode 136 is connected to the p⁺-type anode region 128. In the openings of the interlayer insulating film 124, a barrier metal 125 and a metal plug 143 are formed.

The temperature sensing diode 152, for example, is formed as follows. First, on the field oxide film 132, a non-doped polycrystalline silicon layer is grown, boron (B) ions are implanted in the non-doped polycrystalline silicon layer; the non-doped polycrystalline silicon layer is patterned and etched so as to be left only in the temperature sensing portion; the implanted B ions are heat treated and thereby diffused; a p-type polycrystalline silicon layer is formed and concurrently by a thermal oxide method, a thermal oxide film 123 covering the p-type polycrystalline silicon layer is formed.

Next, B ions are partially implanted, phosphorus (P) ions are partially implanted, and the interlayer insulating film 124 is formed. The interlayer insulating film 124, for example, is a stacked film including a high temperature oxide (HTO) film and a boron phosphosilicate glass (BPSG) film. Next, the implanted B and P ions are heat treated and thereby diffused, forming the n⁺-type cathode region 126 and the p⁺-type anode region 128.

Next, contact holes are formed in the interlayer insulating film 124 by patterning and etching; Al‐Si (an aluminum silicon alloy) is deposited by sputtering; the Al‐Si is patterned and etched, thereby forming the cathode electrode 134 and the anode electrode 136.

Further, a temperature sensor is known that may suppress malfunction due to disturbance noise such as electromagnetic interference by making the capacitance formed between one of two mutually different conductivity type regions constituting a diode and a base region of a semiconductor device element substantially equal to the capacitance formed between the other conductivity type region and the base region of the semiconductor device element (for example, refer to Japanese Laid-Open Patent Publication No. 2002-280556).

Further, a semiconductor device is known in which the temperature detection accuracy of a temperature sensing diode utilizing the temperature dependency of Vf is improved by shortening among a length of a current path from the end of a first contact hole on a side closer to an interface of a pn junction to the interface, and a length of the current path from the end of a second contact hole on the side closer to the interface to the interface, for whichever has the larger sheet resistance among a cathode region and an anode region (for example, refer to International Publication No. WO 2015/87483).

### SUMMARY OF THE INVENTION

According to an embodiment of the present disclosure, a semiconductor device includes: a substrate; an insulating film provided on the substrate; a cathode region of a first conductivity type, provided on the insulating film; an anode region of a second conductivity type, provided on the insulating film; a low-concentration region of the first conductivity type or the second conductivity type, provided between the cathode region and the anode region, the low-concentration region having a dopant concentration lower than a dopant concentration of the cathode region and that of the anode region; an interlayer insulating film covering the cathode region, the anode region, and the low-concentration region, the interlayer insulating film having a first contact hole and a second contact hole penetrating through the interlayer insulating film; a cathode electrode provided on the interlayer insulating film, the cathode electrode being connected to the cathode region via the first contact hole; and an anode electrode provided on the interlayer insulating film, the anode electrode being connected to the anode region via the second contact hole. The low-concentration region has an upper portion, and in a top view of the semiconductor device, the cathode electrode or the anode electrode overlaps the upper portion of the low-concentration region by 4 μm or more in a direction from the cathode region to the anode region.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure of a semiconductor device according to an embodiment.

FIG. 1A is a cross-sectional view depicting another structure of a temperature sensing diode of the semiconductor device according to the embodiment.

FIG. 2 is a cross-sectional view depicting a state of the temperature sensing diode of the semiconductor device according to the embodiment, during manufacture.

FIG. 3 is a cross-sectional view depicting a state of the temperature sensing diode of the semiconductor device according to the embodiment, during manufacture.

FIG. 4 is a cross-sectional view depicting a state of the temperature sensing diode of the semiconductor device according to the embodiment, during manufacture.

FIG. 5 is a cross-sectional view depicting a state of the temperature sensing diode of the semiconductor device according to the embodiment, during manufacture.

FIG. 6 is a cross-sectional view depicting a state of the temperature sensing diode of the semiconductor device according to the embodiment, during manufacture.

FIG. 7 is a cross-sectional view depicting a state of the temperature sensing diode of the semiconductor device according to the embodiment, during manufacture.

FIG. 8 is a cross-sectional view depicting a state of the temperature sensing diode of the semiconductor device according to the embodiment, during manufacture.

FIG. 9 is a cross-sectional view depicting a state of the temperature sensing diode of the semiconductor device according to the embodiment, during manufacture.

FIG. 10 is a cross-sectional view depicting a state of the temperature sensing diode of the semiconductor device according to the embodiment, during manufacture.

FIG. 11 is a cross-sectional view depicting a state of the temperature sensing diode of the semiconductor device according to the embodiment, during manufacture.

FIG. 12 is a cross-sectional view depicting a state of the temperature sensing diode of the semiconductor device according to the embodiment, during manufacture.

FIG. 13 is a cross-sectional view depicting a state when charged particles are irradiated to a temperature sensing diode of a conventional semiconductor device.

FIG. 14 is a cross-sectional view depicting a state when charged particles are irradiated to the temperature sensing diode of the semiconductor device according to the embodiment.

FIG. 15 is a graph depicting change of forward voltage Vft of the temperature sensing diode of the conventional semiconductor device and change of the forward voltage Vft of the temperature sensing diode of the semiconductor device according to the embodiment.

FIG. 16 is a cross-sectional view depicting a structure of the temperature sensing diode of the conventional semiconductor device.

### DETAILED DESCRIPTION OF THE INVENTION

First, problems associated with the conventional technique are discussed. When a constant forward current flows between the anode and cathode, the temperature sensing diode 152 generates forward voltage Vft. The forward voltage Vft decreases when the temperature increases and thus, the temperature sensing diode 152 is an element that uses this characteristic to detect temperature. To increase the accuracy of detection with respect to temperature changes, in the temperature sensing diode 152, the value and distribution of parasitic resistance (sheet resistance and contact resistance in a current path) has to be suppressed. To achieve this, the n⁺-type cathode region 126 and the p⁺-type anode region 128, which are in contact with the cathode electrode 134 and the anode electrode 136, as regions of a high carrier concentration, suppress contact resistance. On the other hand, to stabilize the distribution of the dopant concentration of the pn junction portion and reduce the distribution of sheet resistance, the p⁻-type low-concentration region 130 (or the n⁻-type low-concentration region) having a low carrier concentration is necessary between the n⁺-type cathode region 126 and the p⁺-type anode region 128. The carrier concentration of the n⁺-type cathode region 126 and the p⁺-type anode region 128 is on the order of 1×10¹⁵cm⁻³ while the carrier concentration of the p⁻-type low-concentration region 130 (or the n⁻-type low-concentration region) is on the order of 1×10¹³cm⁻³.

However, a problem arises in that disturbance factors in subsequent processing and prolonged use at high temperatures may cause fluctuations in the resistance of the p-type low-concentration region 130 (or the n-type low-concentration region), resulting in long-term fluctuations in the Vft value.

Embodiments of a semiconductor device and a method of manufacturing a semiconductor device according to the present disclosure will be described in detail with reference to the accompanying drawings. In the present description and accompanying drawings, layers and regions prefixed with n or p mean that majority carriers are electrons or holes. Additionally, + or - appended to n or p means that the impurity concentration is higher or lower, respectively, than layers and regions without + or -. In the description of the embodiments below and the accompanying drawings, main portions that are identical will be given the same reference numerals and will not be repeatedly described. Further, in the present description, when Miller indices are described, "-" means a bar added to an index immediately after the "-", and a negative index is expressed by prefixing "-" to the index. Further, with consideration of variation in manufacturing, description indicating the same or equal may be within 5%.

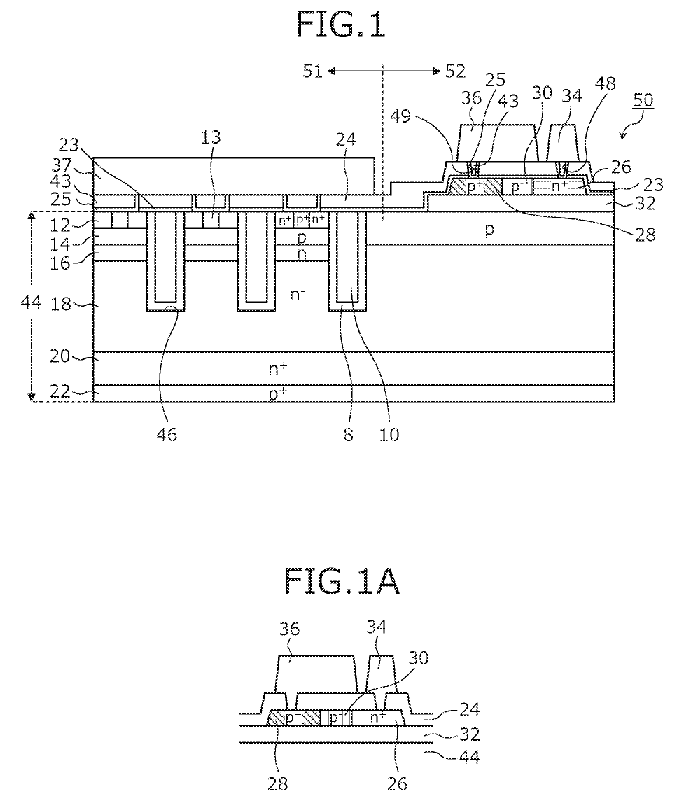

A structure of a semiconductor device according to an embodiment is described taking an IGBT as an example. FIG. 1 is a cross-sectional view depicting the structure of the semiconductor device according to the embodiment. The semiconductor device according to the embodiment is an IGBT 50 having a temperature sensing diode 52.

The IGBT 50 is provided on a single semiconductor substrate in which an IGBT region 51 constituting an operating region of the IGBT and the temperature sensing diode 52 in a temperature sensing region are provided in parallel. In the IGBT 50, in an n⁻-type semiconductor substrate 18 constituting an n⁻-type drift layer, at a front surface thereof, an n-type accumulation layer 16 may be provided. The n-type accumulation layer 16 is a so-called current spreading layer (CSL) that reduces carrier spreading resistance. On the n-type accumulation layer 16 (front side of the n⁻-type semiconductor substrate 18), a p-type base region 14 is provided from the IGBT region 51 to the temperature sensing diode 52. In the IGBT region 51, gate trenches 46 penetrating through the p-type base region 14 to the n⁻-type semiconductor substrate 18 are provided. The gate trenches 46, in a plan view, for example, are disposed at predetermined intervals in the IGBT region 51, extend linearly, and divide the p-type base region 14 into multiple regions (mesa portions); on each side of each of the gate trenches 46, an n⁺-type emitter region 12 is provided. Further, p⁺-type contact regions 13 may be provided so as to be in contact with the n⁺-type emitter regions 12. In the gate trenches 46, gate insulating films 8 are provided along inner walls of the gate trenches 46 and gate electrodes 10 are provided on the gate insulating films 8.

In the IGBT region 51, in the p-type base region 14, the n⁺-type emitter regions 12 and the p⁺-type contact regions 13 are each selectively provided in each of the mesa portions. The n⁺-type emitter regions 12 face the gate electrodes 10 with the gate insulating films 8 provided at the inner walls of the gate trenches 46 intervening therebetween. The n⁺-type emitter regions 12 are provided closer to the gate trenches 46 than are the p⁺-type contact regions 13. The p⁺-type contact regions 13 may be omitted. In an instance in which the p⁺-type contact regions 13 are omitted, at a location farther from the gate trenches 46 than are the n⁺-type emitter regions 12, the p-type base region 14 reaches a front surface of a semiconductor substrate 44 and is exposed at the front surface of the semiconductor substrate 44. In the temperature sensing diode 52, the p-type base region 14 is free of the n⁺-type emitter regions 12. A front electrode 37 is in contact with the n⁺-type emitter regions 12 via contact holes and is electrically insulated from the gate electrodes 10 by an interlayer insulating film 24. In the n⁺-type emitter regions 12, openings are selectively provided and, in the openings, the front electrode 37 and the p-type base region 14 may be electrically connected. The front electrode 37 functions as an emitter electrode in the IGBT region 51.

In the n⁻-type semiconductor substrate 18, at a back surface thereof, an n⁺-type field stop (FS) layer 20 may be provided. The n⁺-type FS layer 20 has a function of suppressing the spreading of a depletion layer that spreads toward a later-described p⁺-type collector region 22, from pn junctions between the p-type base region 14 and the n⁻-type semiconductor substrate 18 during an on-state.

In the n⁻-type semiconductor substrate 18, at the back surface thereof, the p⁺-type collector region 22 is provided at a position closer to the back surface of the n⁻-type semiconductor substrate 18 than is the n⁺-type FS layer 20, and a back electrode (not depicted) is provided at a surface (entire area of the back surface of the n⁻-type semiconductor substrate) of the p⁺-type collector region 22. The back electrode functions as a collector electrode in the IGBT region 51. The p⁺-type collector region 22, the n⁻-type semiconductor substrate 18, the n⁺-type FS layer 20, the n-type accumulation layer 16, and the p-type base region 14 collectively are referred to as the semiconductor substrate 44.

Further, as depicted in FIG. 1, the IGBT 50 includes the temperature sensing diode 52 provided on a main surface of the semiconductor substrate 44, via a field oxide film (insulating film) 32. The temperature sensing diode 52 is for immediately detecting abnormal temperature rises in power elements when the power elements are energized, thereby preventing element destruction due to thermal runaway. The temperature sensing diode 52 is provided in a center of the semiconductor chip and is surrounded by an active region of the IGBT 50, in a plan view. The temperature sensing diode 52 has an n⁺-type cathode region 26 of a first conductivity type (n-type), provided on the field oxide film 32, and a p⁺-type anode region 28 of a second conductivity type (p-type), provided on the field oxide film 32 so as to form a pn junction with the n⁺-type cathode region 26.

Further, a p⁻-type low-concentration region 30 is provided between the n⁺-type cathode region 26 and the p⁺-type anode region 28. Instead of the p⁻-type low-concentration region 30, an n⁻-type low-concentration region (not depicted) may be provided. The temperature sensing diode 52 is formed by a pn junction between the n⁺-type cathode region 26 and the p⁻-type low-concentration region 30 or a pn between the n⁻-type low-concentration region and the p⁺-type anode region 28.

To suppress contact resistance, the n⁺-type cathode region 26 and the p⁺-type anode region 28, which are in contact with a later-described cathode electrode 34 and anode electrode 36, increase the carrier concentration. Further, to stabilize the distribution of the dopant concentration of the pn junction portion and reduce variation of the resistance, the p⁻-type low-concentration region 30 (or the n⁻-type low-concentration region) has a lower carrier concentration than the carrier concentration of the n⁺-type cathode region 26 and the p⁺-type anode region 28. For example, the carrier concentration of the n⁺-type cathode region 26 and the p⁺-type anode region 28 is on the order of 1×10¹⁵cm⁻³ while the carrier concentration of the p⁻-type low-concentration region 30 (or the n⁻-type low-concentration region) is on the order of 1×10¹³cm⁻³. Further, the p⁻-type low-concentration region 30 (or the n⁻-type low-concentration region) have a low carrier concentration and a large sheet resistance and thus, preferably, a width of the p⁻-type low-concentration region 30 (or the n⁻-type low-concentration region) may be narrow and preferably, may be about a few μm.

Further, the n⁺-type cathode region 26 and the p⁺-type anode region 28 are covered by the interlayer insulating film 24. The cathode electrode 34, which is electrically connected to the n⁺-type cathode region 26 via a first contact hole 48 that penetrates through the interlayer insulating film 24, is provided. The anode electrode 36, which is electrically connected to the p⁺-type anode region 28 via a second contact hole 49 that penetrates through the interlayer insulating film 24, is provided. Further, in the embodiment, the interlayer insulating film 24 covers the p⁻-type low-concentration region 30 and is free of a contact hole above the p⁻-type low-concentration region 30. The interlayer insulating film 24 has a similar structure in an instance of the n⁻-type low-concentration region. Further, in the first contact hole 48 and the second contact hole 49, at bottom and side surfaces thereof, a barrier metal 25 containing Ti, titanium nitride (TiN), tantalum (Ta), tantalum nitride (TaN), etc. or stacked layers thereof may be formed. Further, to ensure good connection of the cathode electrode 34 and the anode electrode 36 with the n⁺-type cathode region 26 and the p⁺-type anode region 28, respectively, a metal plug 43 containing tungsten (W) or molybdenum (Mo) may be formed in the first contact hole 48 and in the second contact hole 49. FIG. 1A is a cross-sectional view depicting another structure of the temperature sensing diode of the semiconductor device according to the embodiment. FIG. 1A depicts an example of the temperature sensing diode 52 in an instance in which a thermal oxide film 23, the barrier metal 25, and the metal plug 43 are omitted.

Further, as depicted in FIG. 1, the anode electrode 36 covers an upper portion of the p⁻-type low-concentration region 30. In other words, the p⁻-type low-concentration region 30 is provided in a region facing the anode electrode 36 in a downward direction (direction from the p-type base region 14 to the n⁻-type semiconductor substrate 18). Further, the cathode electrode 34 may cover the upper portion of the p⁻-type low-concentration region 30. An instance of the n⁻-type low-concentration region instead of the p⁻-type low-concentration region 30 is the same. Further, as described later, the cathode electrode 34 and the anode electrode 36 have a function of blocking charged particles/ions and thus, preferably, the cathode electrode 34 and the anode electrode 36 may overlap an upper portion of the n⁺-type cathode region 26 or the p⁺-type anode region 28 and extend 4 μm or more beyond a boundary between the p⁻-type low-concentration region 30 and the p⁺-type anode region 28 or a boundary between the p⁻-type low-concentration region 30 and the n⁺-type cathode region 26, so that penetration of charged particles/ions may be prevented. Further, the cathode electrode 34 and the anode electrode 36 have a function of blocking charged particles/ions and thus, preferably, a thickness thereof may be 4 μm or greater.

The field oxide film 32 is, for example, a silicon dioxide (SiO₂) film. The interlayer insulating film 24 may be, for example, a film containing at least one of HTO, non-doped silicate glass (NSG), a BPSG film. The cathode electrode 34 and the anode electrode 36 are formed by, for example, an aluminum (Al) film or an aluminum alloy film such as an aluminum-silicon (Al-Si) film, an aluminum-copper (Al-Cu) film, an aluminum-copper-silicon (Al-Cu-Si) film, or the like.

Further, bottom and side surfaces of the n⁺-type cathode region 26 and the p⁺-type anode region 28 are covered by the interlayer insulating film 24 and the field oxide film 32. In the IGBT 50 according to the embodiment, while an instance in which the temperature sensing diode 52 is singular is depicted for the sake of convenience, the temperature sensing diode 52 may be provided in plural connected in series to increase the detection voltage. In this instance, the temperature sensing diodes 52 are collectively a temperature sensing diode while each of the individual temperature sensing diodes is a temperature sensing diode unit thereof.

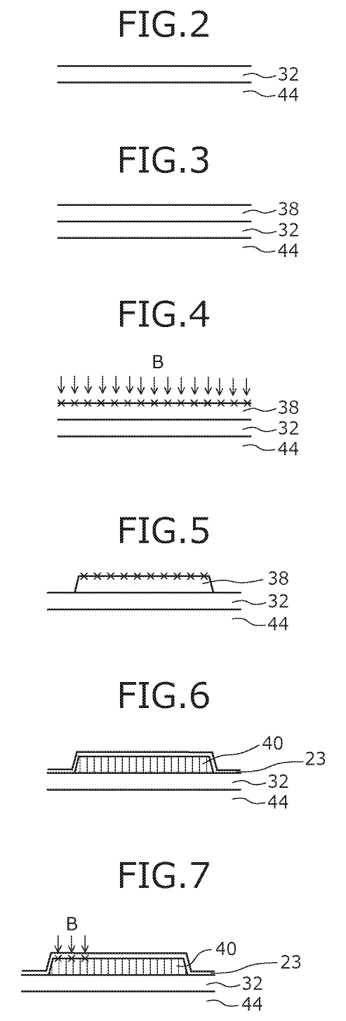

Next, the method of manufacturing the semiconductor device according to the embodiment is described. FIGS. 2, 3, 4, 5, 6, 7, 8, 9, 10, 11 and 12 are cross-sectional views depicting states of the temperature sensing diode of the semiconductor device according to the embodiment, during manufacture.

First, in an entire area of a main surface of the semiconductor substrate 44, the field oxide film 32 is formed. The field oxide film 32 is a silicon dioxide (SiO₂) film formed by a thermal oxide method or the like. The state up to here is depicted in FIG. 2. Next, a non-depicted photoresist is used as an etching mask, the field oxide film 32 on a formation region of the IGBT region 51 is selectively removed by wet etching or the like, the photoresist is successively removed and thereafter, the IGBT region 51 may be formed. The IGBT region 51 is manufactured (fabricated) by a same method as that of a normal IGBT and thus, description of the method of manufacturing thereof is omitted herein.

Next, on the field oxide film (insulating film) 32, a non-doped polycrystalline silicon layer (semiconductor layer) 38 is formed by a chemical vapor deposition (CVD) method. The state up to here is depicted in FIG. 3. Next, in an entire area of the surface of the non-doped polycrystalline silicon layer 38, as a first dopant ion of a p-type, for example, boron (B) ions are implanted (first process). Implantation of the first dopant ion is performed under a condition of, for example, a dose amount of about 1×10¹³cm⁻² to 5×10¹⁴cm⁻². The first dopant ion may be an n-type dopant, such as phosphorus ions or arsenic ions. In an instance in which phosphorus ions or arsenic ions are used as the first dopant ion, the dose amount may be equal to that in an instance in which boron (B) ions are used. The state up to here is depicted in FIG. 4.

Next, a non-depicted photoresist is used as an etching mask, the polycrystalline silicon layer 38 and the field oxide film 32 are left on the formation region of the temperature sensing diode 52 while other portions thereof are selectively removed by dry etching or the like and the photoresist is successively removed. The state up to here is depicted in FIG. 5.

Next, a heat treatment for activating the first dopant ion (boron ions) of the polycrystalline silicon layer 38 is performed, whereby a p-type polycrystalline silicon layer 40 is formed from the polycrystalline silicon layer 38. Here, the thermal oxide film 23 that covers the p-type polycrystalline silicon layer 40 is formed. The thermal oxide film 23 may be a silicon dioxide (SiO₂) film formed by a thermal oxide method or may be a HTO film formed after formation of the p-type polycrystalline silicon layer 40. Formation of the thermal oxide film 23 may be omitted. The state up to here is depicted in FIG. 6.

Next, a non-depicted photoresist is used as an ion-implantation mask and for example, boron (B) ions are implanted, as a second dopant ion of a p- type, in a region of the p-type polycrystalline silicon layer 40, where the p⁺-type anode region 28 is to be formed (second process). The implantation of the second dopant ion is performed under a condition of, for example, a dose amount of a range of about 5×10¹⁴cm⁻² to 5×10¹⁶cm⁻². More preferably, the implantation of the second dopant ion may be performed under a condition of, for example, a dose amount of about 1×10¹⁵cm⁻² to 5×10¹⁶cm⁻². The implantation of the second dopant ion may be performed concurrently with an ion-implantation for forming the p⁺-type contact regions in the IGBT region 51. The state up to here is depicted in FIG. 7.

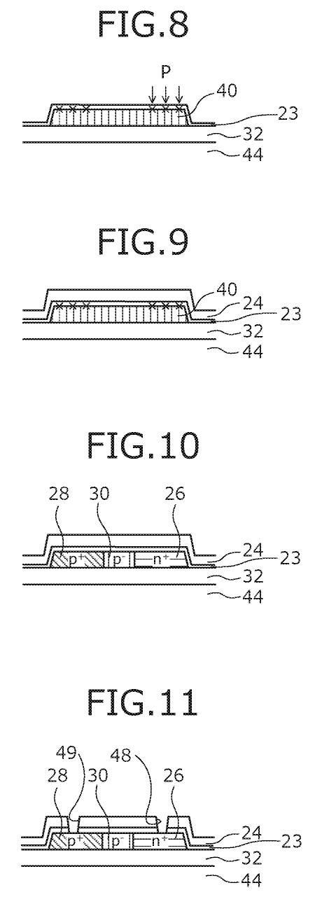

Next, a non-depicted photoresist is used as an ion-implantation mask and, for example, phosphorus (P) ions are implanted as a third dopant ion of an n-type in a region of the p-type polycrystalline silicon layer 40, where the n⁺-type cathode region 26 is to be formed (third process). The implantation of the third dopant ion is performed under a condition of, for example, a dose amount of a range of about 5×10¹⁴cm⁻² to 5×10¹⁶cm⁻². The implantation of the third dopant ion may be performed concurrently with an ion-implantation for forming the n⁺-type emitter regions 12 in the IGBT region 51. Arsenic (As) ions may be used as the third dopant ion of an n-type. In an instance in which arsenic (As) ions are used as the third dopant ion of an n-type, the dose amount may be equal to that in an instance in which phosphorus (P) ions are used. The state up to here is depicted in FIG. 8.

Next, in an entire area of the main surface of the semiconductor substrate 44, the interlayer insulating film 24 is formed by, for example, a CVD method so as to cover the p-type polycrystalline silicon layer 40 (the fifth process). The interlayer insulating film 24 is, for example, any one of a HTO film, an NSG film, and a BPSG film, or a stacked film thereof. The state up to here is depicted in FIG. 9.

Next, a heat treatment for activating the second dopant ion (boron ions) and the third dopant ion (phosphorus ions) of the p-type polycrystalline silicon layer 40 is performed, whereby the n⁺-type cathode region 26, the p⁺-type anode region 28, and the p⁻-type low-concentration region 30 are formed in the p-type polycrystalline silicon layer 40 (fourth process). Here, in the p-type polycrystalline silicon layer 40, in a region thereof in which the p-type dopant ions and the n-type dopant ions are implanted constitute the p⁻-type low-concentration region 30. The state up to here is depicted in FIG. 10.

Next, the first contact hole 48 penetrating through the interlayer insulating film 24 and exposing a portion of the n⁺-type cathode region 26 and the second contact hole 49 penetrating through the interlayer insulating film 24 and exposing a portion of the p⁺-type anode region 28 are formed (sixth process). The state up to here is depicted in FIG. 11.

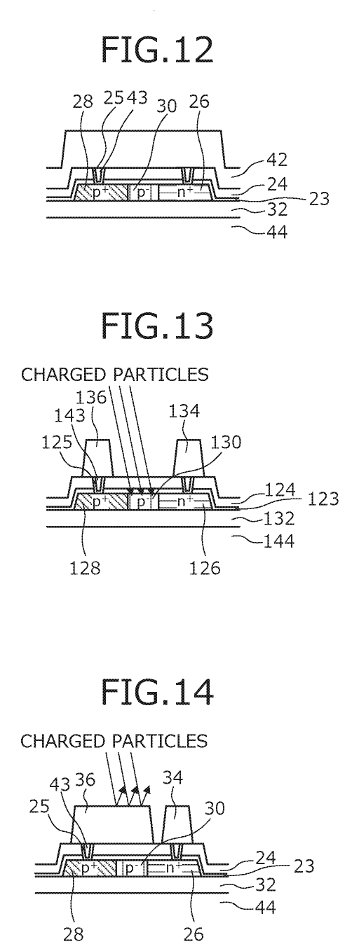

Next, a metal film containing, for example, Al or an Al alloy such as Al-Si is formed on the interlayer insulating film 24 by a sputtering method so as to be embedded in each of the first contact hole 48 and the second contact hole 49 (seventh process). Before this process, the barrier metal 25 containing Ti, TiN, Ta, TaN, etc. or a stacked layer thereof may be formed at the bottom and side surfaces of the first contact hole 48 and of the second contact hole 49. Further, to ensure good connection of the cathode electrode 34 and the anode electrode 36 with the n⁺-type cathode region 26 and the p⁺-type anode region 28, respectively, the metal plug 43 containing W or Mo may be formed the first contact hole 48 and the second contact hole 49. The state up to here is depicted in FIG. 12. Thereafter, this metal film 42 is patterned and etched, thereby forming the cathode electrode 34 and the anode electrode 36 (eighth process). The cathode electrode 34 and the anode electrode 36 may be formed concurrently with the emitter electrode of the IGBT region 51. Here, as depicted in FIG. 1, the anode electrode 36 is patterned to cover the upper portion of the p⁻-type low-concentration region 30. As described, the temperature sensing diode 52 depicted in FIG. 1 is formed.

Further, the cathode electrode 34 may be patterned so as to cover the upper portion of the p⁻-type low-concentration region 30. Moreover, instead of the p⁻-type low-concentration region 30, the n⁻-type low-concentration region may be formed. In this instance, for example, phosphorus ions are implanted as n-type dopant ions in an entire area of the surface of the non-doped polycrystalline silicon layer 38 and the heat treatment for activating the dopant ions (phosphorus ions) of the polycrystalline silicon layer 38 is performed, thereby forming the n-type polycrystalline silicon layer from the polycrystalline silicon layer 38. However, diffusion of B is better than that of P and therefore, formation of the p⁻-type low-concentration region 30 more preferable than formation of the n⁻-type low-concentration region.

Further, either the second process of forming the p⁺-type anode region 28 or the third process of forming the n⁺-type cathode region 26 may be performed between the sixth process of forming the first contact hole 48 and the second contact hole 49, and the seventh process. For example, in an instance in which the p⁻-type low-concentration region 30 is formed, the second process of implanting the second dopant ion (boron ions) may be performed between the sixth process and the seventh process. In this instance, a heat treatment for activating the second dopant ion (boron ions) may be additionally performed.

FIG. 13 is a cross-sectional view depicting a state when charged particles are irradiated to the temperature sensing diode of the conventional semiconductor device. FIG. 14 is a cross-sectional view depicting a state when charged particles are irradiated to the temperature sensing diode of the semiconductor device according to the embodiment. As depicted in FIG. 13, in the temperature sensing diode of the conventional semiconductor device, the cathode electrode 134 and the anode electrode 136 do not cover the upper portion of the p⁻-type low-concentration region 130. While not depicted, an instance of the n⁻-type low-concentration region is the same. Thus, when charged particles/ions (hydrogen, hydrogen molecular ions, polyatomic ions contained in resins used in assembly processes, etc.) are irradiated and dispersed due to disturbance factors in subsequent processing, the charged particles/ions reach the p⁻-type low-concentration region 130 (or the n⁻-type low-concentration region). In this case, the charged particles/ions are captured and bonded to dangling bonds at polysilicon grain boundaries. As a result, at the p⁻-type low-concentration region 130 (or the n⁻-type low-concentration region), the potential barrier height fluctuates, causing fluctuations in the sheet resistance of the p-type low-concentration region 130 (or the n-type low-concentration region), resulting in long-term fluctuations in Vft.

In contrast, in the temperature sensing diode of the semiconductor device according to the embodiment, the cathode electrode 34 or the anode electrode 36 covers the upper portion of the p⁻-type low-concentration region 30. FIG. 14 is a cross-sectional view depicting an instance in which the anode electrode 36 covers the upper portion of the p⁻-type low-concentration region 30. While not depicted, an instance of the n⁻-type low-concentration region is the same. As a result, when charged particles/ions are irradiated and dispersed due to disturbance factors in subsequent processing, the cathode electrode 34 or the anode electrode 36 block the charged particles/ions and thus, charged particles/ions may be prevented from reaching the p⁻-type low-concentration region 30 (or the n⁻-type low-concentration region). Without the charged particles/ions being captured and bonded to dangling bonds at polysilicon grain boundaries, fluctuation of the potential barrier height in the p⁻-type low-concentration region 30 (or the n⁻-type low-concentration region) does not occur, fluctuation of the sheet resistance value of the p⁻-type low-concentration region 30 (or the n⁻-type low-concentration region) does not occur even with prolonged use under high temperatures, and long-term fluctuation in the value of Vft may be suppressed, thereby enabling long-term product reliability to be ensured and electrical characteristics specifications to be guaranteed.

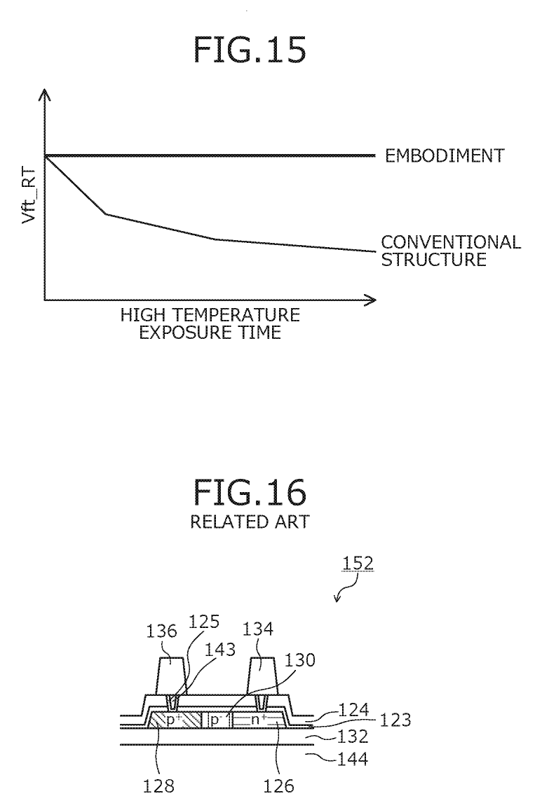

FIG. 15 is a graph depicting change of the forward voltage Vft of the temperature sensing diode of the conventional semiconductor device and change of the forward voltage Vft of the temperature sensing diode of the semiconductor device according to the embodiment. In FIG. 15, a vertical axis indicates the forward voltage Vft_RT at room temperature while a horizontal axis indicates the time that the semiconductor device was left at high temperature. As depicted in FIG. 15, in the temperature sensing diode of the conventional semiconductor device, the forward voltage Vft_RT gradually decreases whereas in the temperature sensing diode of the semiconductor device according to the embodiment, there is almost no decrease in the forward voltage Vft_RT.

As described, according to the embodiment, the cathode electrode or the anode electrode covers the upper portion of the p⁻-type low-concentration region (or the n⁻-type low-concentration region). As a result, when charged particles/ions are irradiated and dispersed due to disturbance factors in subsequent processing, the charged particles/ions may be prevented from reaching the p⁻-type low-concentration region (or the n⁻-type low-concentration region). Without the charged particles/ions being captured and bonded to dangling bonds at polysilicon grain boundaries, fluctuation of the potential barrier height in the p⁻-type low-concentration region (or the n⁻-type low-concentration region) does not occur, fluctuation of the sheet resistance value of the p⁻-type low-concentration region (or the n⁻-type low-concentration region) does not occur even with prolonged use under high temperatures, and long-term fluctuation in the value of Vft may be suppressed, thereby enabling long-term product reliability to be ensured and electrical characteristics specifications to be guaranteed.

In the foregoing, while the present disclosure is described taking a MOS gate structure provided on a first main surface of a silicon substrate as an example, without limitation hereto, various modifications such as in the type of semiconductor (for example, silicon carbide (SiC) or the like), orientation of the main surface of the substrate, and the like are possible. Further, in the embodiment of the present disclosure, while a trench IGBT is described as an example, without limitation hereto, semiconductor devices of various types of configurations such as planar type semiconductor devices, MOSFETs and the like are applicable. Further, in the present disclosure, while the first conductivity type is assumed to be an n-type and the second conductivity type is assumed to be a p-type in the embodiments, the present disclosure is similarly implemented when the first conductivity type is a p-type and the second conductivity type is an n-type.

According to the disclosure described above, the cathode electrode or the anode electrode covers the upper portion of the p⁻-type low-concentration region (or the n⁻-type low-concentration region). As a result, when charged particles/ions are irradiated and dispersed due to disturbance factors in subsequent processing, the charged particles/ions are prevented from reaching the p⁻-type low-concentration region (or the n⁻-type low-concentration region). Without the charged particles/ions being captured and bonded to dangling bonds at polysilicon grain boundaries, fluctuation of the potential barrier height in the p⁻-type low-concentration region 30 (or the n⁻-type low-concentration region) does not occur. Thus, fluctuation of the sheet resistance value of the p⁻-type low-concentration region 30 (or the n⁻-type low-concentration region) does not occur even with prolonged use under high temperatures.

The semiconductor device and the method of manufacturing a semiconductor device according to the present disclosure achieve an effect in that long-term fluctuation in the value of the forward voltage Vft of the temperature sensing diode may be suppressed.

As described, the semiconductor device and the method of manufacturing a semiconductor device according to the present disclosure are useful for high voltage semiconductor devices used in power converting equipment, power source devices of various types of industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a substrate;
an insulating film provided on the substrate;
a cathode region of a first conductivity type, provided on the insulating film;
an anode region of a second conductivity type, provided on the insulating film;
a low-concentration region of the first conductivity type or the second conductivity type, provided between the cathode region and the anode region, the low-concentration region having a dopant concentration lower than a dopant concentration of the cathode region and that of the anode region;
an interlayer insulating film covering the cathode region, the anode region, and the low-concentration region, the interlayer insulating film having a first contact hole and a second contact hole penetrating through the interlayer insulating film;
a cathode electrode provided on the interlayer insulating film, the cathode electrode being connected to the cathode region via the first contact hole; and
an anode electrode provided on the interlayer insulating film, the anode electrode being connected to the anode region via the second contact hole, wherein
the low-concentration region has an upper portion, and
in a top view of the semiconductor device, the cathode electrode or the anode electrode overlaps the upper portion of the low-concentration region by 4 μm or more in a direction from the cathode region to the anode region.

2. The semiconductor device according to claim 1, wherein
the cathode region, the anode region, and the low-concentration region are constituted by a polycrystalline silicon layer.

3. The semiconductor device according to claim 1, wherein
the cathode electrode and the anode electrode each have a thickness of 4 μm or more.

4. A method of manufacturing a semiconductor device, the method comprising:
as a first process, implanting a first dopant ion in a semiconductor layer provided on an insulating film;
as a second process, implanting a second dopant ion in a first region of the semiconductor layer having the first dopant ion implanted therein;
as a third process, implanting a third dopant ion in a second region of the semiconductor layer having the first dopant ion implanted therein;
as a fourth process, activating the first dopant ion, the second dopant ion, and the third dopant ion, thereby forming
an anode region in the first region implanted with the second dopant ion,
a cathode region in the second region implanted with the third dopant ion, and
a low-concentration region in a third region of the semiconductor layer, the third region being implanted with the first dopant ion and being exclusive of the second region and the first region;
as a fifth process, forming an interlayer insulating film covering the semiconductor layer;
as a sixth process, forming a first contact hole penetrating through the interlayer insulating film and exposing a portion of the cathode region, and forming a second contact hole penetrating through the interlayer insulating film and exposing a portion of the anode region;
as a seventh process, forming a metal film covering the interlayer insulating film; and
as an eighth process, selectively removing the metal film thereby forming a cathode electrode connected to the cathode region via the first contact hole, and forming an anode electrode connected to the anode region via the second contact hole, the cathode electrode or the anode electrode being formed so as to overlap an upper portion of the low-concentration region in a top view of the semiconductor device.

5. The method according to claim 4, wherein
in the fourth process, a dose amount of the first dopant ion is in a range of 1×10¹³cm⁻² to 5×10¹⁴cm⁻² and a dose amount of the second dopant ion and that of the third dopant ion are each in a range of 5×10¹⁴cm⁻² to 5×10¹⁶cm⁻².

6. The method according to claim 4, wherein
as the first dopant ion, boron ions, phosphorus ions, or arsenic ions are used,
as the second dopant ion, boron ions are used, and
as the third dopant ion, phosphorus ions or arsenic ions are used.
